(19) United States
(12) Patent Application Publication
(10) Pub. No.: US 2007/0059878 A1
(43) Pub. Date: Mar. 15, 2007

(54) Salicide process

(76) Inventors: Yu-Lan Chang, Kao-Hsiung City (TW); Chao-Ching Hsieh, Hsin-Chu Hsien (TW); Yi-Yiing Chiang, Taipei City (TW); Yi-Wei Chen, Tai-Chung Hsien (TW); Tzung-Yu Hung, Tainan Hsien (TW); Jia-Rung Li, Kao-Hsiung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/162,564

(22) Filed: Sep. 14, 2005

(51) Int. Cl. H01L 21/8238; H01L 21/44

(52) U.S. Cl. 438/233; 438/682; 438/683; 438/685; 438/686; 257/E21.164

(57) ABSTRACT

A salicide process includes providing a substrate, in which the surface of the substrate contains at least a silicon layer; performing a degas process on the substrate; performing a cooling process on the substrate; depositing a metal layer over the surface of the substrate, in which the surface of the metal layer and the surface of the silicon layer are in contact with each other; and removing the unreacted metal layer.

### BACKGROUND OF THE INVENTION

1. Field of the Invention

The present invention relates to a method of fabricating semiconductor devices, and more particularly, to a method of performing salicide processes.

2. Description of the Prior Art

Field effect transistors are important electronic devices in the fabrication of integrated circuits, and as the size of the semiconductor device becomes smaller and smaller, the fabrication of the transistors also improves and is constantly enhanced for fabricating transistors with smaller sizes and higher quality.

In the conventional method of fabricating transistors, a gate structure is first formed on a substrate, and a lightly doped drain (LDD) is formed on the two corresponding sides of the gate structure. Next, a spacer is formed on the sidewall of the gate structure and an ion implantation process is performed to form a source/drain region within the substrate by utilizing the gate structure and spacer as a mask. In order to incorporate the gate, source, and drain into the circuit, contact plugs are often utilized for interconnection purposes, in which the contact plugs are composed of conducting metals such as tungsten and copper. Nevertheless, the interconnection between the contact plugs and the silicon material of the gate structure and the source/drain region is usually poor, hence a silicide material is often formed over the surface of the gate structure and the source/drain region to improve the ohmic contact between the contact plugs and the gate structure and the source/drain region. Today, the process known as self-aligned silicide (salicide) process has been widely utilized to fabricate silicide materials, in which a source/drain region is first formed, a metal layer comprised of cobalt, titanium, or nickel is disposed on the source/drain region and the gate structure, and a rapid thermal process (RTP) is performed to react the metal layer with the silicon contained within the gate structure and the source/drain region to form a metal silicide for reducing the sheet resistance of the source/drain region.

However, when the silicides are being formed, the atoms within the metal layer will diffuse into the substrate and deplete the silicon within the source/drain region, thereby damaging the original lattice structure of the source/drain region and causing the PN junction between the source/drain region and the silicon substrate to react with the silicon contained within the source/drain region as a result of an overly short distance between the PN junction and the silicide layer. Ultimately, the problems become much worse in the design of ultra shallow junctions (USJ) as the silicides often come in contact directly with the substrate and result in failure of the device.

Please refer to FIG. 1 and FIG. 2. FIG. 1 and FIG. 2 are perspective diagrams showing the means of fabricating salicides according to the prior art. As shown in FIG. 1, a gate structure 66 having a gate dielectric layer 62 and a gate electrode 64 is first formed on a substrate 60. Next, an ion implantation process is performed to form a lightly doped drain 70 in the substrate 60. Next, a liner 67 and a spacer 68 are formed on the sidewall of the gate structure 66 and another ion implantation is performed to form a source/drain region 72 in the substrate 60. Next, a wet cleaning process is performed to remove native oxides and other impurities from the surface of the gate structure 66 and the source/drain region 72, and a degas process is performed to remove the remaining water vapor from the wet cleaning process. Next, a sputtering process is performed to form a metal layer 74 over the surface of the gate electrode 64, the spacer 68, and the substrate 60. Subsequently, as shown in FIG. 2, a rapid thermal annealing (RTA) process is performed to react the contact area between the metal layer 74 and the gate electrode 64 and the source/drain region 72 into a silicide layer 76. Next, a selective wet etching process is performed to remove the unreacted metal layer 74 by utilizing mixtures containing ammonia/hydrogen peroxide/water or sulfuric acid/hydrogen peroxide.

In order to prevent the short channel effect of the transistors and improve the interconnect resistance of the integrated circuit, the junction depth of the source and drain needs to be effectively reduced for fabricating transistors containing silicides. However, if the thickness of the silicides on the source and drain is decreased while reducing the junction depth of the source and drain, the interconnect resistance and contact resistance may increase simultaneously. On the other hand, if the depth of the silicides is kept constant, the distance between the PN junction of the source/drain region 112 and the silicon substrate and the silicide layer 116 may become overly short and result in junction leakage. Additionally, the mixture utilized during the wet cleaning process will corrode the liner disposed between the gate electrode and the spacer and cause the silicide to approach the channel area during silicide formation and result in a nickel silicide piping phenomenon.

Moreover, due to high temperature of the PVD chamber or the degas process, the as-deposition formed before the rapid thermal annealing process will result in silicides with polycrystalline structure and degrade the overall thermal stability. In other words, when the treatment temperature is too high or process time of the treatment is too long, the silicides will become pieces of unconnected mass and result in an agglomeration phenomenon and increase the sheet resistance. Additionally, a high temperature will induce a conversion and consume silicon excessively, and cause a spiking phenomenon in the ultra shallow junction or forming a high resistivity structure, such as converting the low resistivity state nickel silicide (NiSi) having less than 20 μ, Ω-cm to a high resistivity state nickel disilicide (NiSi₂) having approximately 50 μ, Ω-cm.

### SUMMARY OF THE INVENTION

It is therefore an objective of the present invention to provide a salicide process to improve the above-mentioned problems.

According to the present invention, a salicide process includes: providing a substrate, wherein the surface of the substrate comprises at least a silicon layer; performing a degas process on the substrate; performing a cooling process on the substrate; depositing a metal layer over the surface of the substrate, wherein the surface of the metal layer and the surface of the silicon layer are in contact with each other; and removing the unreacted metal layer.

Another aspect of the present invention discloses a salicide process, in which the salicide process includes: providing a substrate, wherein the surface of the substrate comprises at least a silicon layer; performing a first low temperature deposition process to form a metal layer over the surface of the substrate, wherein the surface of the metal layer and the surface of the silicon layer are in contact with each other; performing a second low temperature deposition process to form a cap layer over the surface of the metal layer; performing a rapid thermal annealing (RTA) process to form the surface of the silicon layer contacting the metal layer into a silicide layer; and removing the unreacted metal layer and cap layer.

In contrast to the conventional salicide process, the present invention aims to reduce the thermal budget of salicide processes when salicides are formed on the substrate. Consequently, the present invention is able to reduce the effects of the agglomeration phenomenon and increase in sheet resistance caused by an overly high temperature or prolonged treatment time, and at the same improve the spiking phenomenon in the ultra shallow junction and the problem of converting low resistivity nickel silicide (NiSi) to high resistivity nickel disilicide (NiSi₂).

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are perspective diagrams showing the means of fabricating salicides according to the prior art.

FIG. 3 through FIG. 5 are perspective diagrams showing the means of applying a salicide process to the fabrication of MOS transistors according to the present invention.

FIG. 6 is a flow chart diagram showing the means of applying a salicide process to the fabrication of MOS transistors according to the present invention.

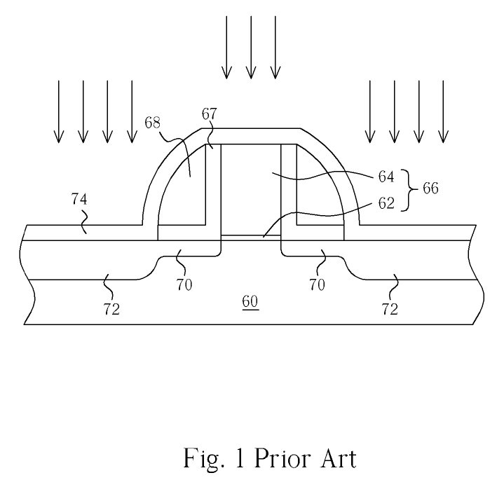

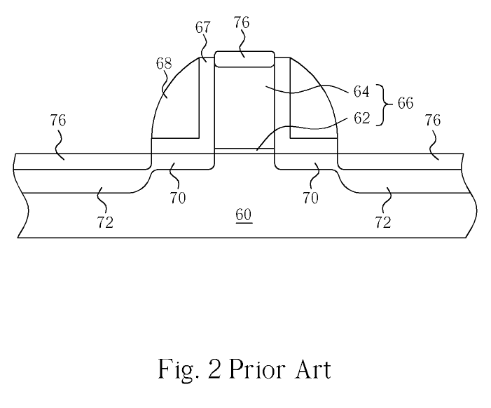

### DETAILED DESCRIPTION

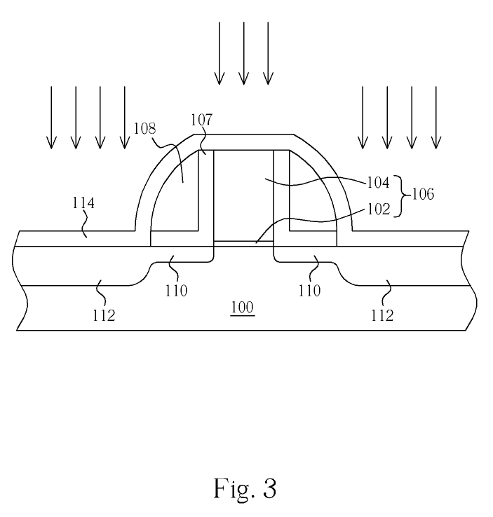

Please refer to FIG. 3 through FIG. 5. FIG. 3 through FIG. 5 are perspective diagrams showing the means of applying a salicide process to the fabrication of MOS transistors according to the present invention. As shown in FIG. 3, a substrate 100, such as a wafer or silicon-on-insulator (SOI) substrate is provided, in which the surface of the substrate 100 includes at least a silicon layer (not shown) composed of single crystal silicon, polysilicon, or epitaxial material. Preferably, the silicon layer may include structures such as gates, source/drain regions, word lines, or resistors depending on different product demands and fabrication processes. According to the preferred embodiment of the present invention, a gate structure 102 and source/drain region 112 of a MOS transistor are utilized as an example, as shown in FIG. 3 through FIG. 5. As shown in FIG. 3, the gate structure 102 includes a gate dielectric layer 102 and gate 104, in which the gate dielectric layer 102 is composed of dielectric material such as silicon dioxide and the gate 104 is composed of conductive material such as doped polysilicon.

Next, a lightly doped ion implantation process is performed to implant a light dopant (not shown) into two sides of the substrate 100 corresponding to the gate 104 to form a source/drain extension region 110 by utilizing the gate 104 as a mask. Next, a liner 107, such as a silicon oxide layer, is deposited around the gate structure 106 and a spacer 108 is formed over the surface of the liner 107, in which the spacer 108 is composed of silicon and oxide composites. Next, a heavily doped ion implantation is performed to implant a heavy dopant (not shown) into the substrate 100 to form a source/drain region 112 with heavier dopant concentration by utilizing the gate 104 and the spacer 108 as a mask. Next, a thermal annealing process utilizing a temperature ranging from 1000° C. to 1020° C. is performed to activate the dopants within the substrate 100 and repair the damage of the crystal lattice structure of the substrate 100 during the ion implantation process.

Subsequently, a wet cleaning step is performed to remove the native oxide and other impurities from the surface of the gate 104 and the source/drain region 112. After the substrate 100 is disposed into a physical vapor deposition (PVD) chamber, a degas process is performed to remove the remaining water vapor from the surface of the substrate 100 by utilizing a temperature between 100° C. and 400° C. Next, a cooling process is performed to cool the substrate 100 to a predetermined temperature, such as below 50° C. by utilizing an inert gas or a wafer cooling chiller to contact the substrate 100, in which the preferred predetermined temperature includes room temperature.

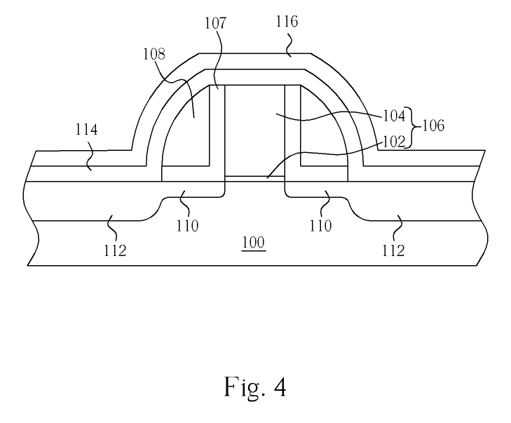

Next, an in-situ deposition is performed by sputtering a metal layer 114 on the substrate 100 and covering the surface of the gate structure 106, the spacer 108, and the source/drain region 112 while controlling the temperature of the PVD chamber under 150° C., as shown in FIG. 3. Preferably, the metal layer 114 is selected from the group consisting of tungsten, cobalt, titanium, nickel, platinum, palladium, and molybdenum. Since part of the silicide, such as NiSi after formation will cause serious junction leakage, a cap layer can be utilized to prevent the oxygen atoms from entering the metal layer 114 during the rapid thermal annealing process performed afterwards and improve the strain of the material on the edge of the device. As shown in FIG. 4, a cap layer 116 composed of titanium or titanium nitride is formed over the surface of the metal layer 114 while maintaining the temperature of the PVD chamber under 150° C. to reduce the oxygen content of the metal layer 114 during rapid thermal annealing process, thereby preventing junction leakage.

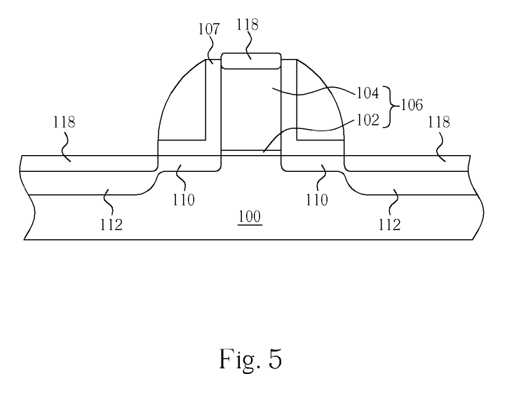

As shown in FIG. 5, a rapid thermal annealing process is performed to heat the substrate 100 to 200-400° C., in which the RTA process is also performed in-situ. When the heating process is performed, the surface of the gate 104 and the source/drain region 112 contacting the metal layer 114 will react and transform into silicide layer 118. After the RTA process, an etching process is performed to remove the unreacted metal layer 114 and cap layer 116 by utilizing a conventional wet etching mixture including ammonia, hydrogen peroxide, hydrochloric acid, sulfuric acid, nitric acid, and acetic acid.

By first performing a cooling process to cool the substrate 100 to room temperature after the 100° C. to 400° C. degas process and then forming a metal layer 114 composed of nickel or other atoms and a cap layer 116 composed titanium or titanium nitride while maintaining the temperature of the PVD chamber under 150° C., the present invention is able to reduce the effects of the agglomeration phenomenon of the as-deposition and the rise of the sheet resistance, thereby improving the spiking phenomenon on the ultra shallow junction. Additionally, the cooling process and the low temperature deposition process performed after the degas process are also able to effectively improve the conventional junction leakage problem caused by an overly high temperature during the metal deposition process, and at the same time decrease the spiking and piping phenomena.

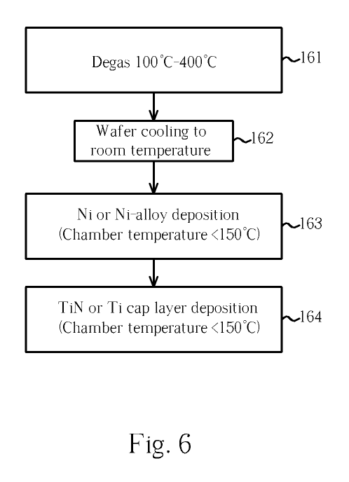

Please refer to FIG. 6. FIG. 6 is a flow chart diagram showing the means of applying a salicide process to the fabrication of MOS transistors according to the present invention. As shown in FIG. 6, a degas process 1 61 is performed on a wafer substrate after disposing the substrate into a fabrication chamber, such a PVD chamber, in which the temperature of the PVD chamber is between 100° C. and 400° C. Next, a cooling process 162 is performed to cool the substrate to a predetermined temperature, such as below 50° C. to decrease the temperature of the wafer from the degas process 161, in which the preferred predetermined temperature includes room temperature. Next, a deposition process is performed to form a metal layer on the wafer substrate while maintaining the temperature of the PVD chamber under 150° C., in which the metal layer is composed of nickel or a nickel alloy. Finally, another deposition process 164 is performed to form a cap layer on the nickel metal layer while maintaining the temperature of the PVD chamber under 150° C., in which the cap layer is composed of titanium or titanium nitride.

In contrast to the conventional salicide process, the present invention aims to reduce the thermal budget of salicide processes when salicides are formed on the substrate. Consequently, the present invention is able to reduce the effects of the agglomeration phenomenon and increase in sheet resistance caused by an overly high temperature or prolonged treatment time, and at the same improve the spiking phenomenon in the ultra shallow junction and the problem of converting low resistivity state nickel silicide (NiSi) to high resistivity state nickel disilicide (NiSi₂).

Those skilled in the art will readily observe that numerous modifications and alterations of the device and method may be made while retaining the teachings of the invention. Accordingly, the above disclosure should be construed as limited only by the metes and bounds of the appended claims.

1. A salicide process comprising:
providing a substrate, wherein the surface of the substrate comprises at least a silicon layer;
performing a degas process on the substrate;
performing a cooling process on the substrate;
depositing a metal layer over the surface of the substrate, wherein the surface of the metal layer and the surface of the silicon layer are in contact with each other; and
removing the unreacted metal layer.

2. The salicide process of claim 1, wherein the substrate comprises a wafer or a silicon-on-insulator (SOI) substrate.

3. The salicide process of claim 1, wherein the silicon layer comprises single crystal silicon, polysilicon, or epitaxial material for forming gate structures, source/drain regions, word lines, or resistors.

4. The salicide process of claim 3, wherein the gate structure further comprises a gate dielectric layer, a polysilicon gate, and at least a spacer disposed around the sidewall of the polysilicon gate.

5. The salicide process of claim 1, wherein the temperature of the degas process is between 100° C. to 400° C.

6. The salicide process of claim 1, wherein the cooling process is performed to cool the substrate after the degas process to a predetermined temperature.

7. The salicide process of claim 6, wherein predetermined temperature is less than 50° C.

8. The salicide process of claim 7, wherein the predetermined temperature comprises room temperature.

9. The salicide process of claim 1, wherein the metal layer is selected from the group consisting of tungsten, cobalt, titanium, nickel, platinum, palladium, and molybdenum.

10. The salicide process of claim 1, further comprising forming a cap layer over the surface of the metal layer.

11. The salicide process of claim 10, wherein the cap layer comprises titanium or titanium nitride.

12. A salicide process comprising:
providing a substrate, wherein the surface of the substrate comprises at least a silicon layer;
performing a cleaning process on the substrate;
performing a degas process on the substrate;
performing a cooling process on the substrate;
performing a first low temperature deposition process to form a metal layer over the surface of the substrate, wherein the surface of the metal layer and the surface of the silicon layer are in contact with each other;
performing a second low temperature deposition process to form a cap layer over the surface of the metal layer;
performing a rapid thermal annealing (RTA) process to form the surface of the silicon layer contacting the metal layer into a silicide layer; and
removing the unreacted metal layer and cap layer.

13. The salicide process of claim 12, wherein the substrate comprises a wafer or a silicon-on-insulator (SOI) substrate.

14. The salicide process of claim 12, wherein the silicon layer comprises single crystal silicon, polysilicon, or epitaxial material for forming gate structures, source/drain regions, word lines, or resistors.

15. The salicide process of claim 14, wherein the gate structure further comprises a gate dielectric layer, a polysilicon gate, and at least a spacer disposed around the sidewall of the polysilicon gate.

16. The salicide process of claim 12, wherein the metal layer is selected from the group consisting of tungsten, cobalt, titanium, nickel, platinum, palladium, and molybdenum.

17. The salicide process of claim 12, wherein the temperature of the first low temperature deposition process is lower than or equal to 150° C.

18. The salicide process of claim 12, wherein the cap layer comprises titanium or titanium nitride.

19. The salicide process of claim 12, wherein the temperature of the second-low temperature deposition process is lower than or equal to 150° C.

20. (canceled)

21. The salicide process of claim 12, wherein the temperature of the degas process is between 100° C. to 400° C.

22. The salicide process of claim 12, wherein the cooling process is performed under 50° C. to cool the substrate after the degas process to a predetermined temperature.

23. The salicide process of claim 22, wherein predetermined temperature comprises room temperature.
